(19) United States
(12) Patent Application Publication
(10) Pub. No.: US 2025/0311474 A1
(43) Pub. Date: Oct. 2, 2025

(54) SEMICONDUCTOR APPARATUS, PHOTOELECTRIC CONVERSION SYSTEM AND MOVING BODY

(71) Applicant: CANON KABUSHIKI KAISHA, Tokyo (JP)

(72) Inventor: SHO SUZUKI, Tokyo (JP)

(21) Appl. No.: 19/087,947

(22) Filed: Mar. 24, 2025

(30) Foreign Application Priority Data
Mar. 27, 2024 (JP) 2024-050943
Dec. 27, 2024 (JP) 2024-231795

(51) Int. Cl. H10F 77/30; H10F 30/22; H10F 77/00

(52) U.S. Cl. CPC H10F 77/306; H10F 30/22; H10F 77/933

(57) ABSTRACT

A semiconductor apparatus includes a first substrate that includes a first wiring structure and a first semiconductor layer, and a second substrate that includes a second wiring structure and a second semiconductor layer, wherein a first metal pattern and a second metal pattern are bonded to electrically connect the first semiconductor layer and the second semiconductor layer, wherein the second semiconductor layer is larger than the first semiconductor layer in a plan view seen from a side with the first semiconductor layer, wherein the second wiring structure includes a guard structure that has a third metal pattern and is disposed at a same height as the second metal pattern, and wherein, in the plan view, a contact portion between the third metal pattern and a diffusion preventing film in contact with the third metal pattern is disposed at a position outside the first semiconductor layer.

### BACKGROUND

### Technical Field

The present disclosure relates to a semiconductor apparatus, a photoelectric conversion system and moving body.

### Description of the Related Art

In recent years, semiconductor apparatuses in which semiconductor layers of different sizes with semiconductor elements are stacked have been known. According to Japanese Patent Application Laid-Open No. 2022-89275, a technique related to Chip-on-Wafer (CoW) is discussed in which a chip including a semiconductor layer and a wiring structure and a wafer including a semiconductor layer and a wiring structure are bonded using copper to copper (Cu—Cu) bonding of metal patterns included in each of the wiring structures. In Cu—Cu bonding, a metal pattern included in a wiring layer of the chip and a metal pattern included in a wiring layer of the wafer are directly bonded. Further, according to Japanese Patent Application Laid-Open No. 2022-89275, it is discussed that a guard structure is disposed in the wiring structure included in the wafer in an area outside the chip in a plan view in order to protect the wiring structure from an effect of dicing in a later process.

According to the technique discussed in Japanese Patent Application Laid-Open No. 2022-89275, protection performance of a semiconductor apparatus is improved by the guard structure formed up to the same layer as the metal pattern included in the wafer, that is, up to a surface where the wafer and the chip are bonded. Further, the guard structure disposed outside the chip in a plan view leads to widening of an area to be used as a circuit included in the wafer.

With the technique discussed in Japanese Patent Application Laid-Open No. 2022-89275, if the guard structure is disposed outside the chip in a plan view up to the same layer as the metal pattern, there is a possibility that a metal element in the metal pattern may diffuse into the semiconductor layer included in the chip, which may deteriorate characteristics of the semiconductor layer included in the chip.

### SUMMARY

A semiconductor apparatus according to the present disclosure is directed to suppressing diffusion of a metal element while protection performance for a semiconductor apparatus is improved.

According to an aspect of the present disclosure, a semiconductor apparatus includes a first substrate that includes a first wiring structure and a first semiconductor layer, and a second substrate that includes a second wiring structure and a second semiconductor layer, wherein a first metal pattern included in the first wiring structure and a second metal pattern included in the second wiring structure are bonded to electrically connect the first semiconductor layer and the second semiconductor layer, wherein the second semiconductor layer is larger than the first semiconductor layer in a plan view seen from a side with the first semiconductor layer, wherein the second wiring structure includes a guard structure that has a third metal pattern and is disposed at a same height as the second metal pattern, and wherein, in the plan view, a contact portion between the third metal pattern and a diffusion preventing film in contact with the third metal pattern is at a position outside the first semiconductor layer.

According to another aspect of the present disclosure, a semiconductor apparatus includes a first substrate that includes a first wiring structure and a first semiconductor layer, and a second substrate that includes a second wiring structure and a second semiconductor layer, wherein a first metal pattern included in the first wiring structure and a second metal pattern included in the second wiring structure are bonded to electrically connect the first semiconductor layer and the second semiconductor layer, wherein the second semiconductor layer is larger than the first semiconductor layer in a plan view seen from a side with the first semiconductor layer, wherein the second wiring structure includes a guard structure that has a third metal pattern and is disposed at a same height as the second metal pattern, wherein, in the plan view, a contact portion between the third metal pattern and a film in contact with the third metal pattern is disposed at a position outside the first semiconductor layer, and wherein the film is made of silicon nitride (SiN), carbon-containing silicon oxide (SiOC), silicon oxynitride (SiON), and carbon-containing silicon nitride (SiCN).

Further features of the present disclosure will become apparent from the following description of exemplary embodiments with reference to the attached drawings.

### BRIEF DESCRIPTION OF THE DRAWINGS

FIGS. 1A to 1C are a schematic plan view and cross-sectional views of a semiconductor apparatus according to a first exemplary embodiment.

FIGS. 2A and 2B are schematic cross-sectional views of a bonding portion of the semiconductor apparatus according to the first exemplary embodiment.

FIGS. 3A and 3B are schematic cross-sectional views of the bonding portion of the semiconductor apparatus according to the first exemplary embodiment.

FIG. 4 is a process cross-sectional view illustrating a manufacturing method of the semiconductor apparatus according to the first exemplary embodiment.

FIG. 5 is a process cross-sectional view illustrating the manufacturing method of the semiconductor apparatus according to the first exemplary embodiment.

FIG. 6 is a process cross-sectional view illustrating the manufacturing method of the semiconductor apparatus according to the first exemplary embodiment.

FIG. 7 is a process cross-sectional view illustrating the manufacturing method of the semiconductor apparatus according to the first exemplary embodiment.

FIGS. 8A to 8C are a schematic plan view and cross-sectional views of a semiconductor apparatus according to a second exemplary embodiment.

FIG. 9 is a process cross-sectional view illustrating a manufacturing method of the semiconductor apparatus according to the second exemplary embodiment.

FIG. 10 is a process cross-sectional view illustrating the manufacturing method of the semiconductor apparatus according to the second exemplary embodiment.

FIG. 11 is a process cross-sectional view illustrating the manufacturing method of the semiconductor apparatus according to the second exemplary embodiment.

FIG. 12 is a process cross-sectional view illustrating the manufacturing method of the semiconductor apparatus according to the second exemplary embodiment.

FIG. 13 is a process cross-sectional view illustrating the manufacturing method of the semiconductor apparatus according to the second exemplary embodiment.

FIG. 14 is a diagram illustrating a configuration of a photoelectric conversion system according to a third exemplary embodiment.

FIGS. 15A and 15B are diagrams illustrating a configuration and operation of a moving body according to a fourth exemplary embodiment.

### DESCRIPTION OF THE EMBODIMENTS

Exemplary embodiments of the present disclosure will be described in detail with reference to the drawings. The exemplary embodiments do not limit the present disclosure according to the claims. Although a plurality of features are described in the exemplary embodiments, all of the plurality of features are not necessarily essential to the present disclosure, and the plurality of features may be arbitrarily combined. In the accompanying drawings, the same or similar components are denoted by the same reference numerals, and redundant description will be omitted.

In the following exemplary embodiments, a photoelectric conversion device is described as an example of a semiconductor device. The semiconductor device in each of the exemplary embodiments can also be used for light-emitting devices and other applications. While an imaging device is used as an example of the photoelectric conversion device in the following description, it is not limited to this. For instance, the semiconductor device is also applicable to photoelectric conversion devices, such as distance measuring devices (e.g., devices for distance measurement using focus detection or Time Of Flight (TOF)) and photometric devices (e.g., devices for measuring the amount of incident light).

In the exemplary embodiments, connections between circuit elements may be described. In such cases, even in a case where another element is interposed between elements of interest, the elements of interest are considered to be connected unless otherwise specified. For example, suppose an element A is connected to one node of a capacitor element C, which has multiple nodes, and an element B is connected to the other node. In such cases, the elements A and B are considered to be connected unless otherwise specified.

The metal component, such as wiring and pads, described in this specification may be composed of a single metal element or a mixture (alloy). For example, the wiring described as copper wiring may be composed of pure copper or may primarily contain copper with additional components. Similarly, the pads connected to external terminals may be composed of pure aluminum or may primarily contain aluminum with additional components. The copper wiring and aluminum pads mentioned here are examples and can be replaced with various metals.

In the following description, a wafer refers to a substrate before dicing, on which multiple semiconductor elements are formed through semiconductor processing, and a chip refers to an individual semiconductor element after the wafer has been diced. The wafer may have a plurality of imaging elements or a plurality of circuit sections thereon, for example.

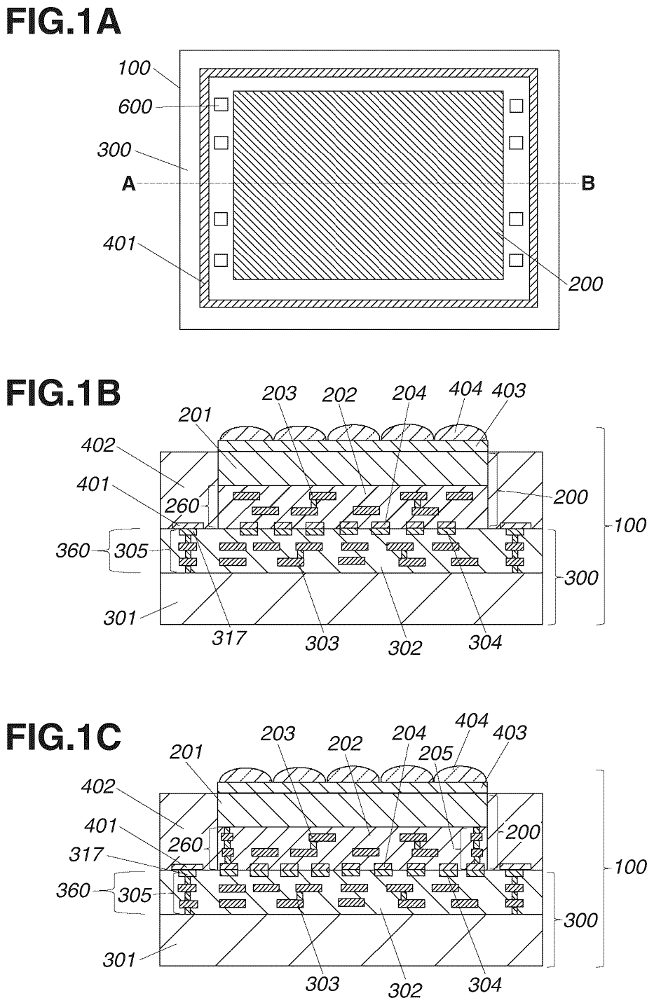

A semiconductor apparatus 100 (photoelectric conversion apparatus) and a manufacturing method thereof according to a first exemplary embodiment of the present disclosure are described with reference to FIGS. 1A to 1C to FIG. 7.

A schematic configuration of the semiconductor apparatus 100 is described with reference to FIGS. 1A to 1C. FIG. 1A is a schematic plan view of the semiconductor apparatus 100, and FIG. 1B is a schematic cross-sectional view taken along an A-B plane in FIG. 1A. In the present specification, a plane refers to a surface viewed from a side of a semiconductor layer 201 (first semiconductor layer side) in a stacked structure of the semiconductor layer 201 (first semiconductor layer) and a semiconductor layer 301 (second semiconductor layer), which are described below. Further, a cross section refers to a surface viewed in a direction perpendicular to a stacked direction of the semiconductor layers 201 and 301, that is, a surface passing through the semiconductor layers 201 and 301. A plan view refers to a case where the above-described plane is viewed, and a cross sectional view refers to a case where the cross section passing through the semiconductor layers 201 and 301 is viewed. For example, a plan view refers to a view in a direction orthogonal to a surface on which a plurality of pixels is arranged in a two-dimensional array.

The semiconductor apparatus 100 includes a substrate 200 (first substrate) including the semiconductor layer 201 and a wiring structure 260 (first wiring structure), and a substrate 300 (second substrate) including the semiconductor layer 301, and a wiring structure 360 (second wiring structure) as illustrated in FIGS. 1A to 1C. The wiring structure 260 includes a plurality of wiring layers 203 and a wiring interlayer film 202 arranged between the wiring layers 203. Each of the wiring layers 203 includes a plurality of metal patterns, and the wiring interlayer film 202 is also disposed between the metal patterns. Further, there is a case where a metal pattern in a certain wiring layer and a metal pattern in an adjacent wiring layer are electrically connected to each other through a via plug. Similarly, the wiring structure 360 includes a plurality of wiring layers 303 and a wiring interlayer film 302 disposed between the wiring layers 303. Each of the wiring layers 303 includes a plurality of metal patterns, and the wiring interlayer film 302 is also disposed between the metal patterns.

The semiconductor layer 201 includes a first semiconductor element, and the semiconductor layer 301 includes a second semiconductor element. A description will be given of an example in which the substrate 200 is configured as an imaging element and the substrate 300 is configured as a circuit unit. In the following example, in the substrate 200, the semiconductor layer 201 includes a photodiode as the first semiconductor element which is a photoelectric conversion element. Further, in the substrate 300, the semiconductor layer 301 includes a signal processing circuit as the second semiconductor element that processes a signal from a photoelectric conversion element. The first semiconductor element may be an element other than a photoelectric conversion element and may be an element such as a transistor or a light emitting element. In a case where the first semiconductor element is a light emitting element, the second semiconductor element may be, for example, a circuit that controls light emission of the light emitting element.

A plurality of pixels each including a photoelectric conversion element, a transfer transistor, an amplification transistor, and a reset transistor is arranged in the semiconductor layer 201. A configuration that includes at least one photoelectric conversion element is regarded as a pixel. A case in which one pixel includes a photoelectric conversion element, a transfer transistor, an amplification transistor, and a reset transistor is described below. A source of the transfer transistor is connected to the photoelectric conversion element, and a drain of the transfer transistor is connected to a gate electrode of the amplification transistor. A node that is the same as the gate electrode of the amplification transistor serves as a floating diffusion (FD). The reset transistor is connected to the FD and sets a potential of the FD to a certain potential (for example, a reset potential). Here, the amplification transistor is a part of a source follower circuit and outputs a signal corresponding to the potential of the FD to a signal line.

Arrangement of the amplification transistor and the reset transistor is not limited to this. For example, the amplification transistor and the reset transistor may be arranged in the semiconductor layer 301. With this configuration, it is possible to increase an area of the photoelectric conversion element and improve sensitivity compared with a case where all the components of the pixel are arranged in the semiconductor layer 201. Further, even in a case where the area of the photoelectric conversion element is not increased, more photoelectric conversion elements are able to be arranged, whereby the number of pixels is increased.

A peripheral circuit that includes a readout circuit and a control circuit is arranged in the semiconductor layer 301. The peripheral circuit includes a vertical scanning circuit, which is a control circuit that supplies a control signal to a gate electrode of the transistor in the pixel. Further, the peripheral circuit includes the readout circuit that stores a signal output from the pixel and performs signal processing, such as amplification, addition, and analog-to-digital (AD) conversion. Furthermore, the peripheral circuit includes a horizontal scanning circuit, which is a control circuit that controls a timing at which signals are sequentially output from the readout circuit.

The first semiconductor element may be an avalanche photodiode. In this case, the transistor may not be arranged in the semiconductor layer 201.

The semiconductor apparatus 100 is configured by bonding the substrates 200 and 300. The wiring layer of the wiring structure 260 on a surface of the substrate 200 on a side with the second substrate includes a metal pattern 204 (first metal pattern). Further, the wiring layer of the wiring structure 360 on a surface of the substrate 300 on a side with the substrate 200 includes a metal pattern 304 (second metal pattern). The substrates 200 and 300 are electrically connected by bonding the metal patterns included in the respective substrates. For example, the metal patterns 204 and 304 may each be made of a material containing copper (Cu) as a main component and may be electrically connected by Cu—Cu bonding.

The substrate 300 includes a guard structure 305 on the outside of the substrate 200 in a plan view. The guard structure 305 is provided to prevent the second semiconductor element of the substrate 300 from being affected by dicing when the semiconductor apparatus 100 is diced into individual pieces. It is desirable that the guard structure 305 is connected to the semiconductor layer 301 and includes a metal layer formed up to a surface of the substrate 300 (a surface which is bonded to the substrate 200). For example, as illustrated in FIG. 1B, it is desirable that the guard structure 305 is disposed in such a manner that a plurality of contact plugs, metal patterns, and via plugs are arranged from a surface of the semiconductor layer 301 to an upper surface of the substrate 300 and the metal is continuously connected. With this configuration, the semiconductor apparatus 100 is less susceptible to dicing.

The guard structure 305 includes a metal pattern (third metal pattern) 317 that is a part of a bonding surface of the substrate 300. The metal pattern 317 is arranged at the same height as the metal pattern 304. The metal pattern 317 is disposed outside the semiconductor layer 201 in a plan view. At least a part of the guard structure 305 is disposed outside the substrate 200 in a plan view, so that it is possible to expand an area of the substrate 300 that is effectively used. In a plan view, a contact portion between the metal pattern 317 and a diffusion preventing film 401 that is in contact with the metal pattern 317 is disposed outside the semiconductor layer 201. In other words, the contact portion is disposed at a position outside an edge (edge portion) of the semiconductor layer 201 in a plan view.

The metal pattern 317 is electrically conducted to the semiconductor layer 301. For example, the metal pattern 317 is supplied with a fixed potential. Accordingly, it is possible to prevent a defect that may occur due to the metal pattern 317 being floating.

The guard structure 305 is, for example, an enclosing shape in a plan view. If a metal element contained in the metal pattern 317 included in the guard structure 305 diffuses into the semiconductor layer 201, characteristics of the substrate 200 may degrade. In other words, protection performance for the semiconductor apparatus may be deteriorated. Thus, according to the present exemplary embodiment, the diffusion preventing film 401 (film) is disposed to be in contact with the metal pattern 317 of the guard structure 305 in order to prevent diffusion of the metal element. It is desirable that the diffusion preventing film 401 is arranged to cover an upper part of the guard structure 305 in a cross sectional view. For example, as illustrated in FIG. 1A, the diffusion preventing film 401 may be arranged in an enclosing shape in a plan view. Further, the wiring structure 260 of the substrate 200 may be provided with a guard structure.

The guard structure 305 may be made of a material other than metal. It is sufficient as long as the second semiconductor element is less susceptible to the effect of dicing, and the guard structure 305 may have a configuration in which an insulating material different from the wiring interlayer film 302 is disposed between the metal patterns instead of a metal via plug.

As illustrated in FIG. 1C, the substrate 200 may include a guard structure 205 as well. The guard structure 205 is provided to prevent the first semiconductor element of the substrate 200 from being affected by dicing which is performed when the substrate 200 is diced into individual pieces. It is desirable that the guard structure 205 is connected to the semiconductor layer 201 and includes a metal layer formed up to a surface of the substrate 200. The guard structure 205 may further be connected to the metal pattern 304.

As illustrated in FIG. 1A, a plurality of pads 600 is arranged inside the guard structure 305. Each of the pads 600 has a function of outputting a signal (image signal) based on a charge generated in the photoelectric conversion element to the substrates 200 and 300 and a function of inputting a voltage for driving the peripheral circuit supplied from the outside. FIG. 1A illustrates an example in which the pads 600 are arranged on the substrate 300, but the pads 600 may be arranged on the substrate 200.

In the substrate 200 of the semiconductor apparatus 100, optical structures, such as a color filter 403 and a microlens 404 are arranged on a surface opposite to a circuit substrate serving as the substrate 300.

As described above, the semiconductor apparatus according to the present exemplary embodiment is a backside illuminated type stacked sensor using Chip-on-Wafer (CoW) technology.

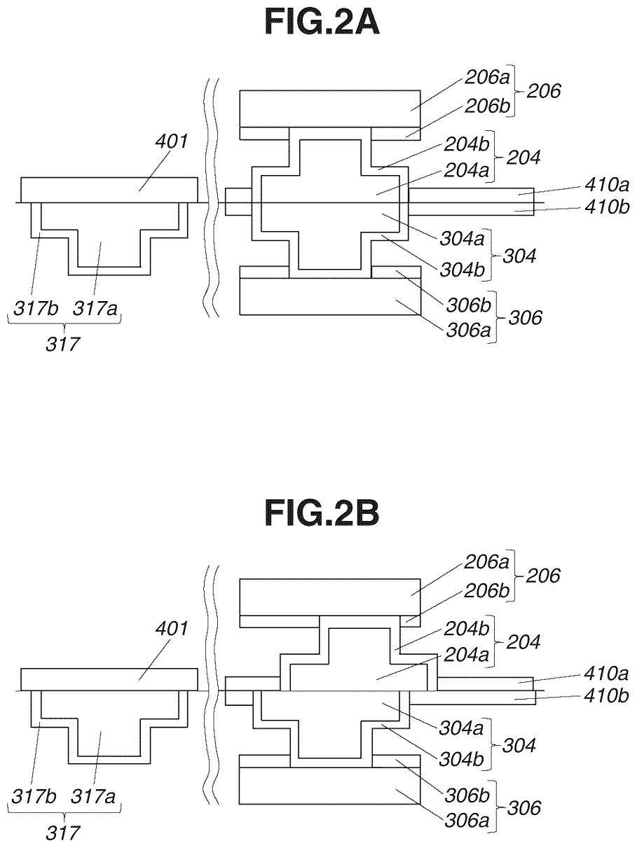

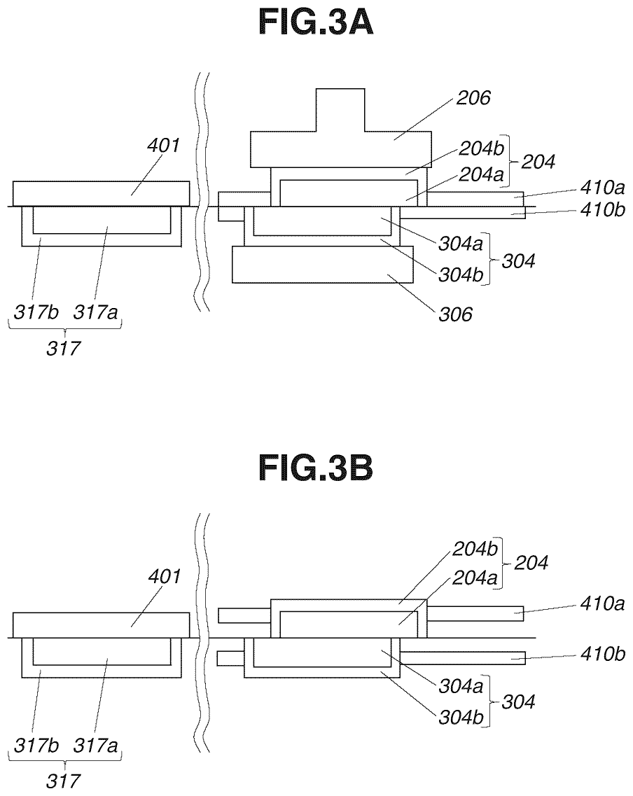

FIGS. 2A, 2B, 3A, and 3B illustrate examples of patterns in enlarged views of the metal patterns 204, 304, and 317 on the bonding surface between the substrates 200 and 300. Any example may be used according to the present exemplary embodiment.

As illustrated in FIGS. 2A, 2B, 3A, and 3B, the metal patterns 204, 304, and 317 may respectively include conductors 204a, 304a, and 317a and conductive films 204b, 304b, and 317b made of a material different from the conductors. The conductors 204a, 304a, and 317a may each be made of a different material, but desirably be made of the same material. Further, the conductive films 204b, 304b, and 317b function as films that prevent diffusion of metal elements in the conductors. The conductive films 204b, 304b, and 317b may each be made of a different material, but desirably be made of the same material. It is desirable that the conductor is covered with a conductive film on its side surfaces and a surface opposite to a surface in contact with another conductor. Accordingly, the conductor is covered with the conductive film even after bonding, so that occurrence of dark current or leak current is suppressed. For example, copper (Cu) may be used as a conductor.

In the following, a case in which the conductors 204a, 304a, and 317a are made of the same material, and the conductive films 204b, 304b, and 317b are made of the same material is described. In the following description, wiring has a single damascene structure formed using a single damascene method in which a trench to be wiring is formed in a wiring interlayer film and a conductive film functioning as a barrier metal and a conductor such as copper are embedded therein, and thus includes the wiring embedded in the wiring interlayer film. Wiring with a dual damascene structure includes wiring and a via that are integrally formed and embedded in a wiring interlayer film. The wiring is formed using a dual damascene method in which a trench to be wiring and a via is formed in the wiring interlayer film and a conductive film functioning as a barrier metal and a conductor such as copper are embedded therein.

In FIG. 2A, the conductor 204a of the metal pattern 204 is in contact with the conductor 304a of the metal pattern 304. Further, the conductive film 204b is disposed in contact with the conductor 204a to cover the conductor 204a except for a contact surface with the conductor 304a. The conductive film 204b is disposed in contact with a metal pattern 206 of an adjacent wiring layer. The metal pattern 206 includes a conductor 206a and a conductive film 206b. The conductor 206a is mainly made of, for example, Cu, and the conductive film 206b is mainly made of, for example, a material that prevents diffusion of Cu. The conductive film 206b may also be disposed on a side opposite a side of the metal pattern 204. The conductive film 204b penetrates a portion of the conductive film 206b and is in contact with the conductor 206a.

The conductor 317a of the metal pattern 317 is in contact with the diffusion preventing film 401. Thus, the conductor 317a is prevented from diffusing.

As illustrated in FIG. 2B, the metal patterns 204 and 304 may be misaligned at the bonding surface. In this case, the conductor 204a is in contact with both the conductor 304a and the conductive film 304b. Further, if the metal patterns 204 and 304 are misaligned at bonding, there is a possibility that the metal element in the conductor of each metal pattern will diffuse into the wiring interlayer film. In order to prevent diffusion of metal of the metal patterns 204 and 304, diffusion preventing films 410a (a second diffusion preventing film or a second film) and 410b are disposed. The diffusion preventing films 410a and 410b are disposed before bonding the substrates 200 and 300 as described below and prevent the diffusion of the metal elements of the metal patterns 204 and 304. As for the metal pattern 317, since the substrate 200 having a chip shape is bonded to the substrate 300 having a wafer shape, it is difficult to leave the diffusion preventing film of the metal pattern 317 alone. Thus, the diffusion preventing films 410a and 401 may be formed in different processes.

The diffusion preventing films 410a and 401 may be made of different materials or the same material. For example, the diffusion preventing film 410a may be made of silicon nitride or the like. As illustrated in FIGS. 2A and 2B and other drawings, it is desirable that the diffusion preventing film 401 is thicker than the diffusion preventing film 410a. The diffusion preventing films 401 and 410a may have the same thickness.

The thickness of the diffusion preventing film 401 is desirably within a range of, for example, 10 nm to 300 nm and more desirably within a range of 20 nm to 150 nm. The thickness of the diffusion preventing film 401 is desirably set within a range of, for example, ½ to ⅕ times a thickness of the metal pattern 317. In FIG. 3A, shapes of the metal patterns 204, 304, and 317 are different from those in FIG. 2B. The metal pattern 206 may include a conductor and a conductive film.

Further, as illustrated in FIG. 3B, the diffusion preventing films 410a and 410b may be disposed at positions away from the bonding surface. Even with this configuration, it is possible to prevent the diffusion of the metal elements from the metal patterns 204 and 304 to the adjacent wiring layers.

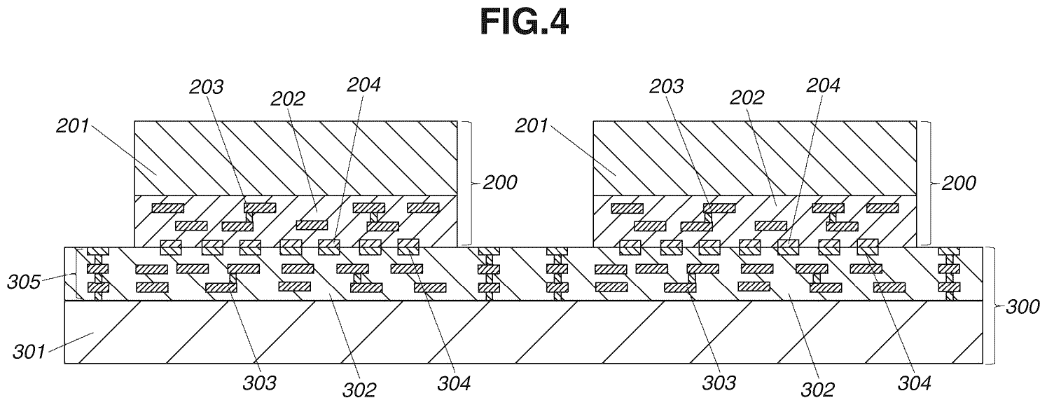

Next, a manufacturing method of the semiconductor apparatus according to the present exemplary embodiment is described with reference to FIGS. 4 to 7. FIGS. 4 to 7 are process cross-sectional views illustrating the manufacturing method of the semiconductor apparatus according to the present exemplary embodiment.

In FIG. 4, the substrate 200 including a chip-shaped imaging element is bonded to the substrate 300 in a wafer state including a plurality of circuit units. The substrates 300 and 200 are respectively provided with the metal patterns 304 and 204 mainly made of, for example, Cu and may be bonded by Cu—Cu metal bonding and covalent bond between the wiring interlayer films 202 and 302.

In this process, a diffusion preventing film containing, for example, silicon nitride (SiN) is formed on a part of the wiring interlayer films 202 and 302, so that it is possible to suppress the diffusion of the metal elements contained in the metal pattern 304 of the wiring layer and the metal pattern 204 of the wiring layer. In this process, the guard structure 305 is in a state in which the wiring layer in the same layer as the wiring layer in which the metal pattern 304 is disposed is exposed.

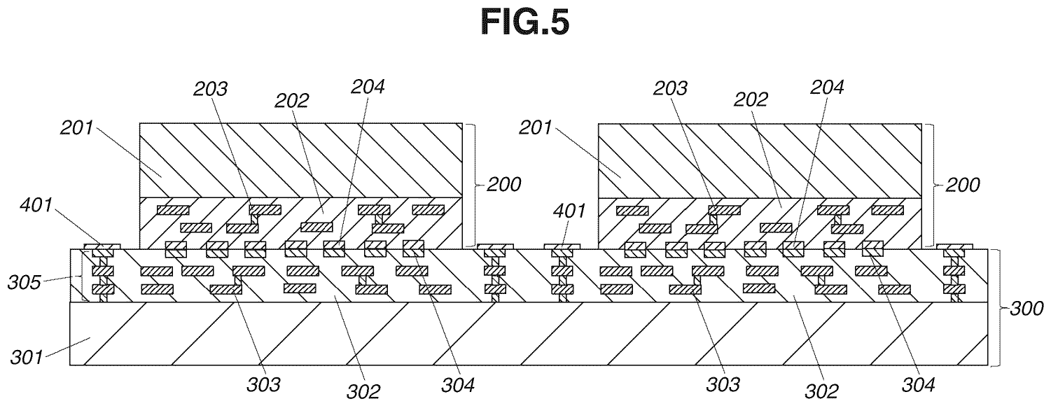

Next, as illustrated in FIG. 5, for example, a silicon nitride film is deposited, and then the diffusion preventing film 401 is formed using photolithography and etching techniques. As a material of the diffusion preventing film 401, silicon oxynitride (SiON), carbon-containing silicon oxide (SiOC), or carbon-containing silicon nitride (SiCN) is used instead of silicon nitride. When the diffusion preventing film 401 is formed, a film similar to the diffusion preventing film may remain on a side surface of the substrate 200, and in this case, it is possible to improve moisture resistance of the substrate 200. Further, the diffusion preventing film 401 is removed from a surface of the semiconductor apparatus 100 to be diced, so that a defect such as peeling of a film during dicing is avoided.

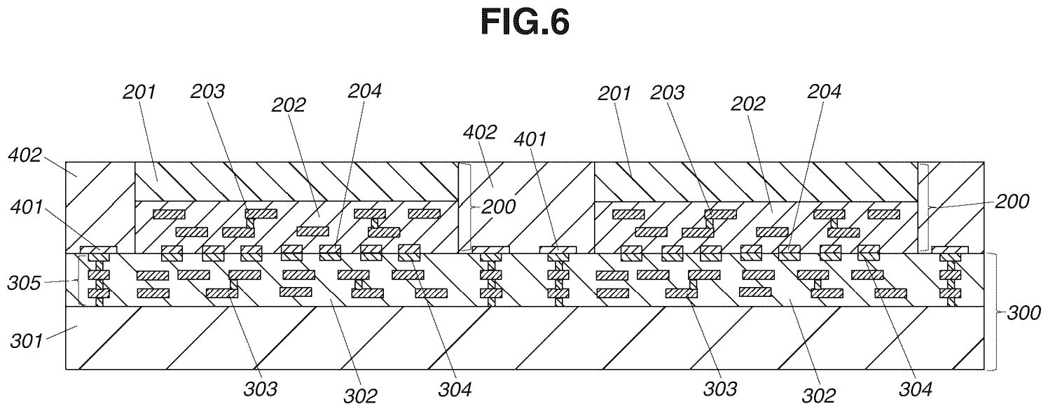

Subsequently, as illustrated in FIG. 6, for example, silicon oxide is deposited and planarized to form the insulating film 402, and the semiconductor layer 201 is further thinned to a suitable thickness. A process for thinning the semiconductor layer 201 may be performed using, for example, chemical mechanical polishing (CMP) and may include a process for controlling a film thickness using a difference in etching rate with respect to a chemical solution due to a difference in impurity concentration contained in the semiconductor layer 201.

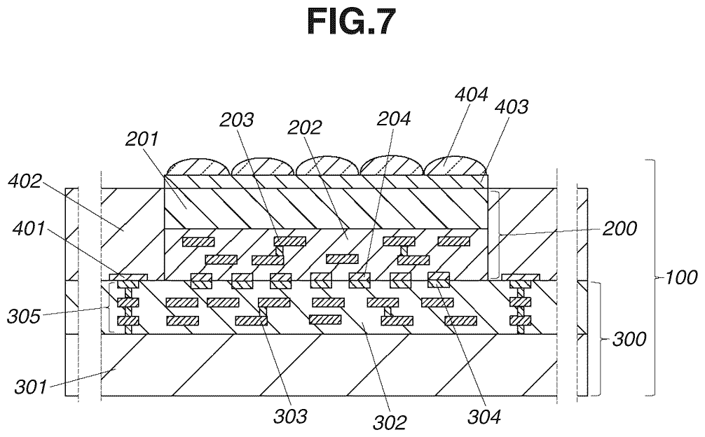

Then, as illustrated in FIG. 7, the optical structures, such as the color filter 403 and the microlens 404, are formed on the semiconductor layer 201, and dicing is performed to separate the semiconductor apparatus into individual pieces, so that the semiconductor apparatus illustrated in FIGS. 1A to 1C is acquired.

According to the semiconductor apparatus of the present exemplary embodiment, the metal pattern of the guard structure 305 is covered with the diffusion preventing film 401, so that a defect in the semiconductor layer 201 caused by diffusion of the metal element in the metal pattern is prevented. Further, according to the manufacturing method of the semiconductor apparatus of the present exemplary embodiment, the guard structure 305 prevents a defect in the substrate 300 caused by dicing, and a defect such as peeling of the diffusion preventing film 401 is also be prevented because the diffusion preventing film 401 is formed after dicing.

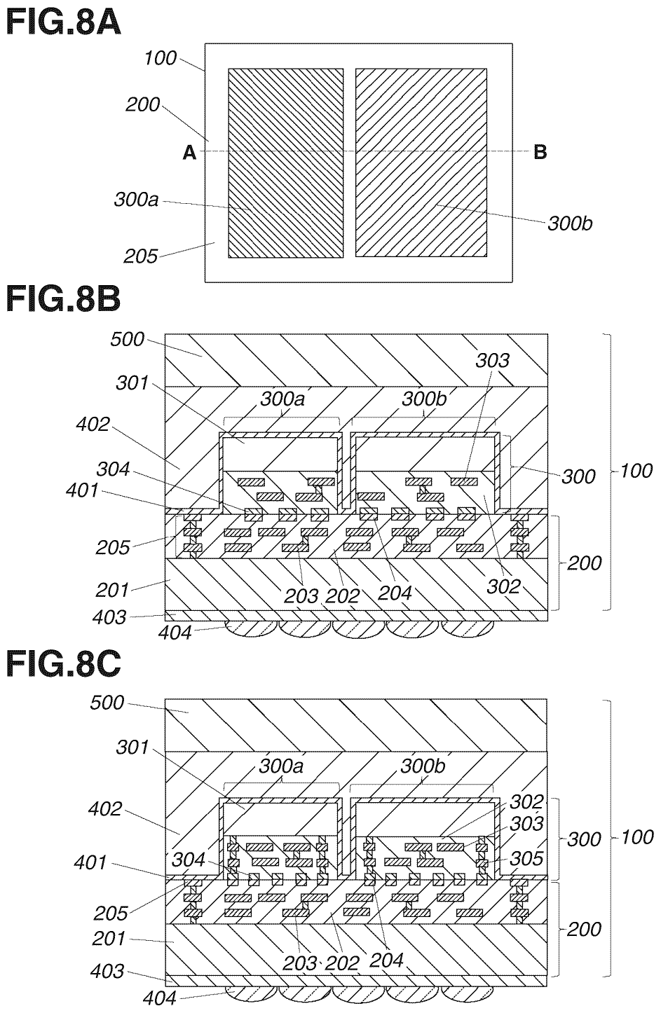

A semiconductor apparatus and a manufacturing method thereof according to a second exemplary embodiment of the present disclosure are described with reference to FIGS. 8A to 8C to 13.

A schematic configuration of the semiconductor apparatus according to the present exemplary embodiment is described with reference to FIGS. 8A to 8C. FIG. 8A is a schematic plan view of the semiconductor apparatus according to the present exemplary embodiment, and FIG. 8B is a cross-sectional view taken along an A-B plane in FIG. 8A.

The second exemplary embodiment is different from the first exemplary embodiment in that a circuit unit that is a substrate 300 (first substrate) in a chip state is bonded to a substrate 200 (second substrate) in a wafer state. Further, the substrate 300 includes a memory circuit 300a and a logic circuit 300b as separate chips, which are bonded to one imaging element included in the substrate 200. Other than these points and points described below, the configuration is substantially the same as that according to the first exemplary embodiment, and thus description thereof may be omitted.

According to the present exemplary embodiment, the semiconductor layer 201 of the substrate 200 is larger than the semiconductor layer 301 of the substrate 300 in a plan view.

The substrate 200 includes the guard structure 205. The guard structure 205 is similar to the guard structure 305 described in the first exemplary embodiment and includes the metal pattern on the bonding surface with the substrate 300. The metal pattern of the guard structure 205 is covered with the diffusion preventing film 401. Thus, it is possible to prevent the metal element of the metal pattern of the guard structure 205 from diffusing into the semiconductor layer 301. Further, at least a part of the guard structure 205 is disposed outside the memory circuit 300a and the logic circuit 300b in a plan view.

As illustrated in FIG. 8C, the substrate 300 may include the guard structure 305. The guard structure 305 is similar to the guard structure 205 described in the first exemplary embodiment and may be connected to the metal pattern 204.

A supporting substrate 500 is disposed on a side of the substrate 300 opposite to the substrate 200. Further, similarly to the first exemplary embodiment, the optical structures, such as the color filter 403 and the microlens 404 are arranged on a surface of the substrate 200 opposite to the substrate 300.

The diffusion preventing film 401 is disposed not only on the guard structure 205 but also on a side surface and a surface of the substrate 300 opposite to the bonding surface. As illustrated in FIG. 8B, it is desirable that the diffusion preventing film 401 continuously covers surfaces other than the bonding surface with the substrate 200. In FIG. 8B, the diffusion preventing film 401 covers side surfaces of the memory circuit 300a and the logic circuit 300b and the surface opposite to the bonding surface with the substrate 200.

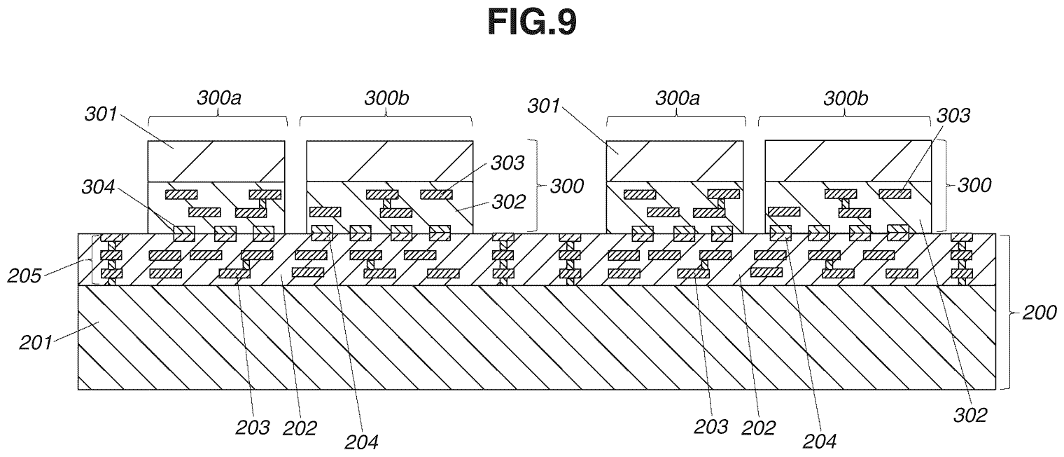

Next, the manufacturing method of the semiconductor apparatus according to the present exemplary embodiment is described with reference to FIGS. 9 to 13. FIGS. 9 to 13 are process cross-sectional views illustrating the manufacturing method of the semiconductor apparatus according to the present exemplary embodiment.

In FIG. 9, the substrate 300 configured with the memory circuit 300a and the logic circuit 300b both in chip-shape is bonded to the substrate 200 in a wafer state on which a plurality of imaging elements is disposed. According to the present exemplary embodiment, two circuit chips are bonded to one imaging element, but the number of circuit chips to be bonded may be one, or three or more circuit chips may be bonded. The memory circuit 300a and the logic circuit 300b are bonded by Cu—Cu metal bonding and covalent bond between the wiring interlayer films 202 and 302 as in the first exemplary embodiment. A process for thinning the semiconductor layer 301 may be performed after bonding the chips. At least a part of the guard structure 205 is disposed outside the memory circuit 300a and the logic circuit 300b in a plan view.

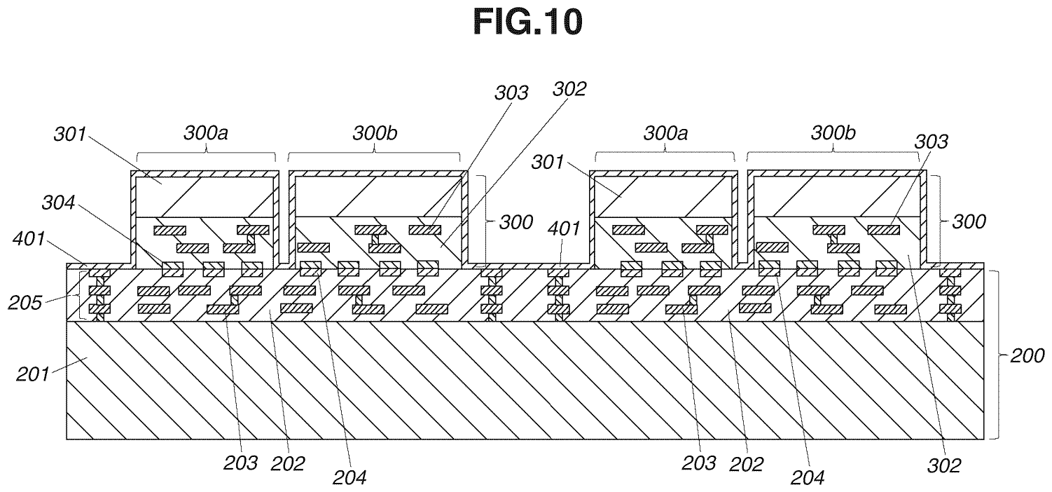

Next, as illustrated in FIG. 10, silicon nitride (SiN) is deposited as the diffusion preventing film 401. As in the first exemplary embodiment, a material such as silicon oxynitride (SiON), carbon-containing silicon oxide (SiOC), or carbon-containing silicon nitride (SiCN) may be used for the diffusion preventing film 401 instead of silicon nitride. Among these, it is desirable to use silicon nitride or silicon oxynitride from the viewpoint of improving moisture resistance. According to the present exemplary embodiment, the diffusion preventing film 401 is left on the side and upper surfaces of the memory circuit 300a and the logic circuit 300b, so that the moisture resistance of the memory circuit 300a and the logic circuit 300b is improved.

As in the first exemplary embodiment, a process may be performed to remove a part of silicon nitride to be the diffusion preventing film 401. In a case where the removing process is performed, for example, the diffusion preventing film 401 is removed from a dicing surface, so that a defect such as peeling of a film during dicing is avoided.

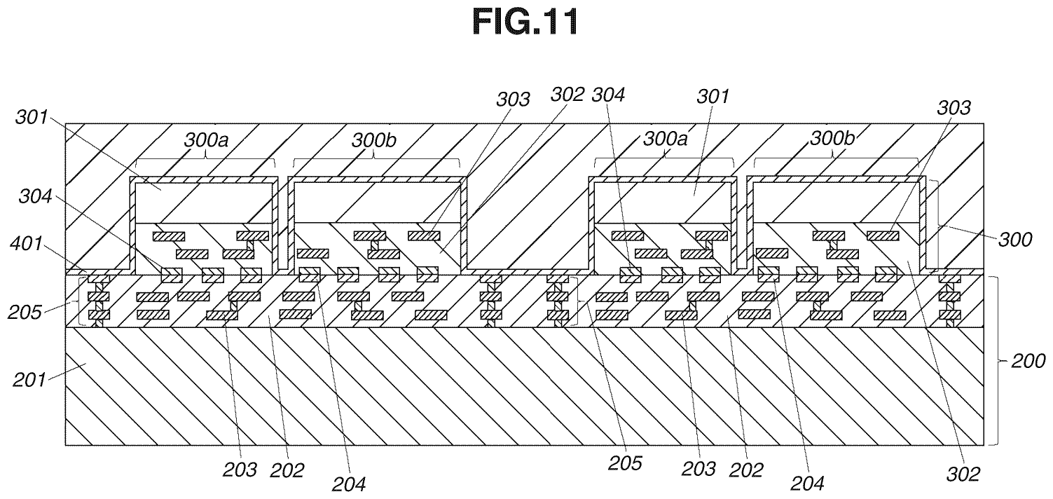

Next, as illustrated in FIG. 11, for example, silicon oxide is deposited and planarized. After the planarization, a bonding layer made of, for example, silicon nitride or silicon oxynitride may be formed on the upper surface.

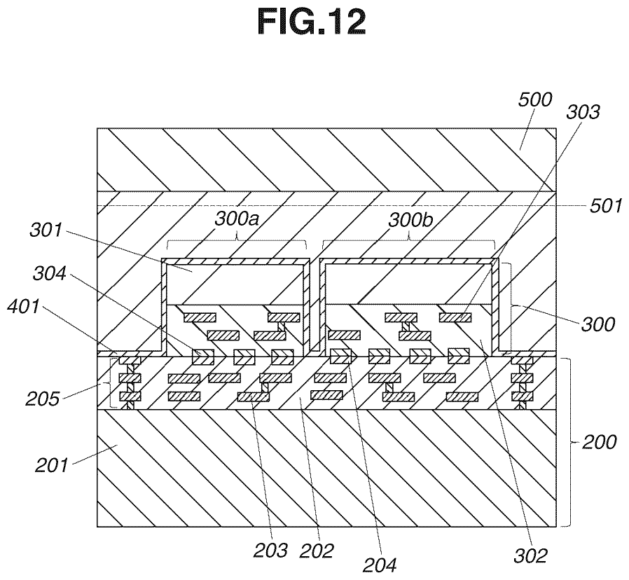

Subsequently, as illustrated in FIG. 12, bonding is performed to the supporting substrate 500 via a bonding surface 501. A bonding layer made of silicon nitride or silicon oxynitride is formed on the supporting substrate 500. Then, the bonding layers made of silicon nitride or silicon oxynitride are bonded to each other at the bonding surface 501.

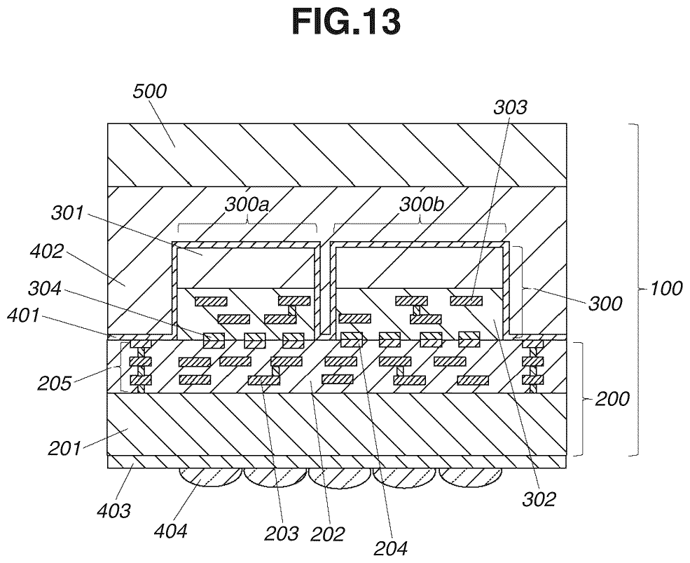

Next, as illustrated in FIG. 13, a process for thinning the semiconductor layer 201 is performed, and the optical structures, such as the color filter 403 and the microlens 404 are formed.

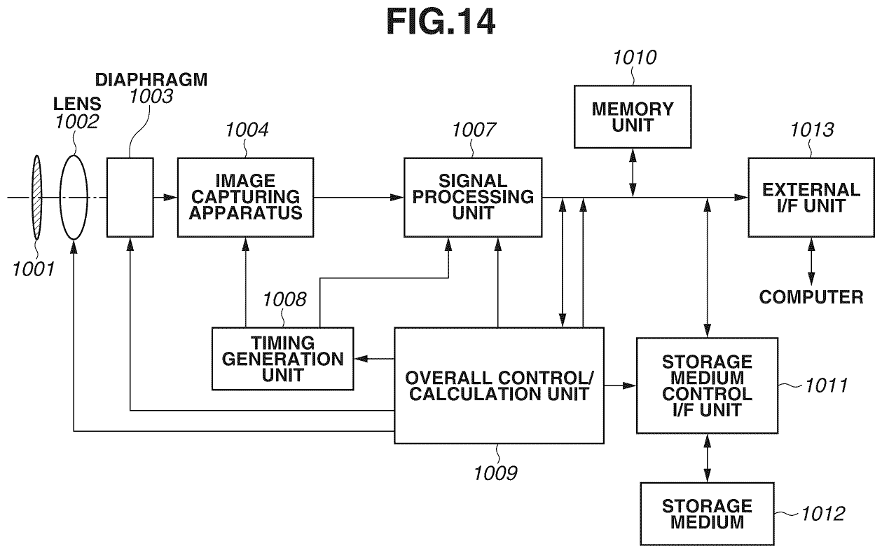

A photoelectric conversion system according to a third exemplary embodiment of the present disclosure is described with reference to FIG. 14. FIG. 14 is a block diagram illustrating a schematic configuration of the photoelectric conversion system according to the present exemplary embodiment.

The semiconductor apparatus (image capturing apparatus) according to the above-described first and second exemplary embodiments is applicable to various photoelectric conversion systems. Examples of an applicable photoelectric conversion system include a digital still camera, a digital camcorder, a surveillance camera, a copy machine, a facsimile machine, a mobile phone, an on-vehicle camera, and an observation satellite. Further, a camera module including an optical system such as a lens and an image capturing apparatus is also included in the photoelectric conversion system. FIG. 14 is a block diagram illustrating a digital still camera as an example of the photoelectric conversion system.

The photoelectric conversion system illustrated in FIG. 14 includes an image capturing apparatus 1004, which is an example of a semiconductor apparatus, and a lens 1002, which forms an optical image of an object on the image capturing apparatus 1004. The image capturing apparatus 1004 further includes a diaphragm 1003 for varying an amount of light passing through the lens 1002 and a barrier 1001 that protects the lens 1002. The lens 1002 and the diaphragm 1003 are optical systems that focus light onto the image capturing apparatus 1004. The image capturing apparatus 1004 is the semiconductor apparatus (image capturing apparatus) according to any one of the above-described exemplary embodiments and converts the optical image formed by the lens 1002 into an electrical signal.

The photoelectric conversion system also includes a signal processing unit 1007, which is an image generation unit that generates an image by processing an output signal output from the image capturing apparatus 1004. The signal processing unit 1007 performs operation of various corrections and compression as necessary and outputting image data. The signal processing unit 1007 may be disposed on a semiconductor substrate on which the image capturing apparatus 1004 is disposed or may be disposed on a semiconductor substrate different from that of the image capturing apparatus 1004. Further, the image capturing apparatus 1004 and the signal processing unit 1007 may be disposed on the same semiconductor substrate.

The photoelectric conversion system further includes a memory unit 1010 that temporarily stores image data and an external interface (I/F) unit 1013 that communicates with an external computer or the like. Furthermore, the photoelectric conversion system includes a storage medium 1012, such as a semiconductor memory, that records and reads out imaging data, and a storage medium control interface (I/F) unit 1011 that performs recording and reading on the storage medium 1012. The storage medium 1012 may be built in or be detachable from the photoelectric conversion system.

The photoelectric conversion system further includes an overall control/calculation unit 1009 that controls various calculations and an entire digital still camera and a timing generation unit 1008 that outputs various timing signals to the image capturing apparatus 1004 and the signal processing unit 1007. Here, a timing signal and the like may be input from the outside, and the photoelectric conversion system may include at least the image capturing apparatus 1004 and the signal processing unit 1007 that processes an output signal output from the image capturing apparatus 1004.

The image capturing apparatus 1004 outputs an imaging signal to the signal processing unit 1007. The signal processing unit 1007 performs predetermined signal processing on the imaging signal output from the image capturing apparatus 1004 and outputs image data. The signal processing unit 1007 generates an image using the imaging signal.

In this way, according to the present exemplary embodiment, the photoelectric conversion system to which the semiconductor apparatus (image capturing apparatus) according to any one of the above-described exemplary embodiments is applied is realized.

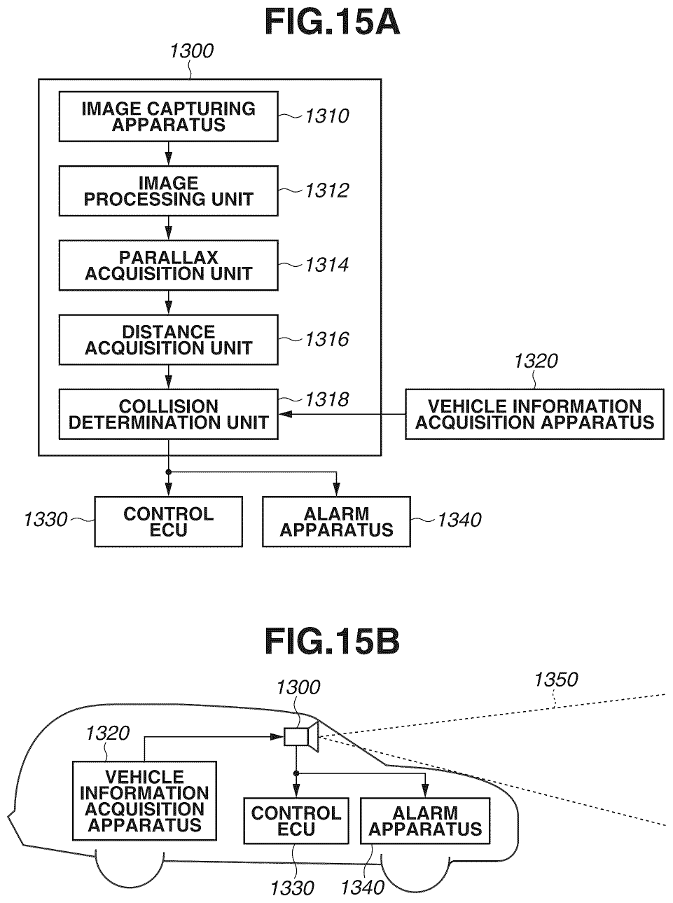

A photoelectric conversion system and a moving body according to a fourth exemplary embodiment of the present disclosure are described with reference to FIGS. 15A and 15B. FIGS. 15A and 15B illustrate configurations of the photoelectric conversion system and the moving body according to the present exemplary embodiment.

FIG. 15A illustrates an example of the photoelectric conversion system relating to an on-vehicle camera. A photoelectric conversion system 1300 includes an image capturing apparatus 1310. The image capturing apparatus 1310 is the semiconductor apparatus (image capturing apparatus) according to any one of the above-described exemplary embodiments. The photoelectric conversion system 1300 includes an image processing unit 1312 that performs image processing on a set of image data acquired by the image capturing apparatus 1310. The photoelectric conversion system 1300 further includes a parallax acquisition unit 1314 that calculates parallax (a phase difference of parallax images) from the set of image data acquired by the photoelectric conversion system 1300. The photoelectric conversion system 1300 also includes a distance acquisition unit 1316 that calculates a distance to a target object based on the calculated parallax and a collision determination unit 1318 that determines whether there is a possibility of collision, based on the calculated distance. Here, the parallax acquisition unit 1314 and the distance acquisition unit 1316 are examples of distance information acquisition units that acquire distance information to the target object. Specifically, the distance information is information regarding parallax, a defocus amount, a distance to the target object, and the like. The collision determination unit 1318 may use any of the distance information to determine the possibility of collision. The distance information acquisition unit may be realized using specially designed hardware or a software module. The distance information acquisition unit may also be realized using a field programmable gate array (FPGA), an application specific integrated circuit (ASIC), and a combination thereof.

The photoelectric conversion system 1300 is connected to a vehicle information acquisition apparatus 1320 and acquires vehicle information, such as a vehicle speed, a yaw rate, and a steering angle. Further, the photoelectric conversion system 1300 is connected to a control engine control unit (ECU) 1330, which is a control unit that outputs a control signal for generating a braking force to the vehicle based on a determination result by the collision determination unit 1318. The photoelectric conversion system 1300 is also connected to an alarm apparatus 1340 that issues an alarm to a driver based on the determination result by the collision determination unit 1318. For example, in a case where there is a high possibility of collision as the determination result by the collision determination unit 1318, the control ECU 1330 performs vehicle control to avoid the collision and reduce damage by applying a brake, releasing an accelerator, or suppressing an engine output. The alarm apparatus 1340 issues an alarm to a user by sounding an alarm, displaying alarm information on a screen of a car navigation system or the like, or vibrating a seat belt or a steering wheel.

According to the present exemplary embodiment, the photoelectric conversion system 1300 captures an image of surroundings of the vehicle, for example, front or rear of the vehicle. FIG. 15B illustrates the photoelectric conversion system 1300 in a case where an image of the front of the vehicle (an image capturing range 1350) is captured. The vehicle information acquisition apparatus 1320 transmits an instruction to the photoelectric conversion system 1300 or the image capturing apparatus 1310. With this configuration, accuracy of distance measurement is further improved.

While an example of controlling a vehicle to avoid collision with another vehicle is described above, the present disclosure is also applicable to control to automatically drive a vehicle by following another vehicle or control to automatically drive a vehicle to prevent the vehicle from running out of its lane. Further, the photoelectric conversion system is applicable to not only a vehicle such as an automobile but also, for example, a moving body (mobile apparatus) such as a ship, an aircraft, or an industrial robot. The moving body includes one or both of a driving force generation unit that generates a driving force that is mainly used to move the moving body and a rotating body that is mainly used to move the moving body. The driving force generation unit may be an engine, a motor, or the like. The rotating body may be a tire, a wheel, a ship's screw, a propeller, or the like. In addition, the photoelectric conversion system is applicable to not only the moving body but also a device that widely uses object recognition, such as intelligent transport systems (ITS).

### Modified Exemplary Embodiment

The present disclosure is not limited to the above-described exemplary embodiments and can be modified in various ways.

For example, an example in which a part of the configuration of any one of the exemplary embodiments is added to another exemplary embodiment, or an example in which a part of the configuration of another exemplary embodiment is substituted therefor is also included in the exemplary embodiments of the present disclosure.

Further, the photoelectric conversion systems according to the above-described third and fourth exemplary embodiments are examples of the photoelectric conversion systems to which the semiconductor apparatus is applicable, and the photoelectric conversion system to which the semiconductor apparatus of the present disclosure is applicable is not limited to the configuration illustrated in FIGS. 14, 15A, and 15B.

The exemplary embodiments are implementation examples of the present disclosure and should not be interpreted as limiting the technical scope of the present disclosure. In other words, the present disclosure can be implemented in various forms without departing from its technical concept or main features.

The disclosure of this specification includes the complement of the concepts described herein. That is, if this specification states, for example, “A is B” (A=B), it implies or suggests “A is not B” (A≠B) even if “A is not B” is not explicitly stated. This is because stating “A is B” inherently considers the case where “A is not B.”

The exemplary embodiments can be appropriately modified without departing from the technical concept. The disclosure of this specification includes not only what is described herein but also all matters that can be understood from the specification and the accompanying drawings. The disclosure also includes the complement of the concepts described herein. For example, if this specification states “A is greater than B,” it implies “A is not greater than B” even if “A is not greater than B” is not explicitly stated. This is because stating “A is greater than B” inherently considers the case where “A is not greater than B.”

According to the present disclosure, a semiconductor apparatus can be provided that suppresses diffusion of a metal element to a semiconductor layer included in a chip while protection performance to the semiconductor apparatus is improved.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Applications No. 2024-050943, filed Mar. 27, 2024, and No. 2024-231795, filed Dec. 27, 2024, which are hereby incorporated by reference herein in their entirety.

What is claimed is:

1. A semiconductor apparatus comprising:
a first substrate that includes a first wiring structure and a first semiconductor layer; and
a second substrate that includes a second wiring structure and a second semiconductor layer,
wherein a first metal pattern included in the first wiring structure and a second metal pattern included in the second wiring structure are bonded to electrically connect the first semiconductor layer and the second semiconductor layer,
wherein the second semiconductor layer is larger than the first semiconductor layer in a plan view seen from a side with the first semiconductor layer,
wherein the second wiring structure includes a guard structure that has a third metal pattern and is disposed at a same height as the second metal pattern, and
wherein, in the plan view, a contact portion between the third metal pattern and a diffusion preventing film in contact with the third metal pattern is disposed at a position outside the first semiconductor layer.

2. The semiconductor apparatus according to claim 1, wherein the third metal pattern is made of a material mainly containing cupper.

3. The semiconductor apparatus according to claim 2, wherein the diffusion preventing film is made of silicon nitride, carbon-containing silicon oxide, silicon oxynitride, and carbon-containing silicon nitride.

4. The semiconductor apparatus according to claim 3, wherein the diffusion preventing film is arranged continuously up to a side surface of the first semiconductor layer.

5. The semiconductor apparatus according to claim 1, wherein the third metal pattern is electrically conducted to the second semiconductor layer.

6. The semiconductor apparatus according to claim 1, wherein, in a cross section passing through the first semiconductor layer and the second semiconductor layer, the third metal pattern is connected to a contact plug connected to the second semiconductor layer via at least one of a metal pattern and a via plug.

7. The semiconductor apparatus according to claim 6, wherein the third metal pattern is connected to the second semiconductor layer through the contact plug, the metal pattern, and the via plug in a continuous manner in the cross section.

8. The semiconductor apparatus according to claim 1, wherein the first semiconductor layer includes a photoelectric conversion element.

9. The semiconductor apparatus according to claim 1, wherein the second semiconductor layer includes a photoelectric conversion element.

10. The semiconductor apparatus according to claim 5, wherein the diffusion preventing film extends up to a side with the first semiconductor layer opposite to a side with the second semiconductor layer.

11. The semiconductor apparatus according to claim 1,
wherein at least one of the first metal pattern and the second metal pattern is in contact with a second diffusion preventing film, and
wherein a thickness of the diffusion preventing film is greater than a thickness of the second diffusion preventing film.

12. The semiconductor apparatus according to claim 1, wherein the contact portion is disposed at a position outside an edge of the first semiconductor layer in the plan view.

13. A semiconductor apparatus comprising:
a first substrate that includes a first wiring structure and a first semiconductor layer; and
a second substrate that includes a second wiring structure and a second semiconductor layer,
wherein a first metal pattern included in the first wiring structure and a second metal pattern included in the second wiring structure are bonded to electrically connect the first semiconductor layer and the second semiconductor layer,
wherein the second semiconductor layer is larger than the first semiconductor layer in a plan view seen from a side with the first semiconductor layer,
wherein the second wiring structure includes a guard structure that has a third metal pattern and is disposed at a same height as the second metal pattern,
wherein, in the plan view, a contact portion between the third metal pattern and a film in contact with the third metal pattern is disposed at a position outside the first semiconductor layer, and
wherein the film is made of silicon nitride, carbon-containing silicon oxide, silicon oxynitride, and carbon-containing silicon nitride.

14. The semiconductor apparatus according to claim 13, wherein the third metal pattern is made of a material mainly containing cupper.

15. The semiconductor apparatus according to claim 13, wherein the film extends up to a side surface of the first semiconductor layer.

16. The semiconductor apparatus according to claim 13, wherein the third metal pattern is electrically conducted to the second semiconductor layer.

17. The semiconductor apparatus according to claim 13, wherein, in a cross section passing through the first semiconductor layer and the second semiconductor layer, the third metal pattern is connected to a contact plug connected to the second semiconductor layer via at least one of a metal pattern and a via plug.

18. The semiconductor apparatus according to claim 17, wherein the third metal pattern is connected to the second semiconductor layer through the contact plug, the metal pattern, and the via plug in a continuous manner in the cross section.

19. The semiconductor apparatus according to claim 13, wherein the first semiconductor layer includes a photoelectric conversion element.

20. The semiconductor apparatus according to claim 13, wherein the second semiconductor layer includes a photoelectric conversion element.

21. The semiconductor apparatus according to claim 15, wherein the film extends up to a side with the first semiconductor layer opposite to a side with the second semiconductor layer.

22. The semiconductor apparatus according to claim 13,
wherein at least one of the first metal pattern and the second metal pattern is in contact with a second film, and
wherein a thickness of the film is greater than a thickness of the second film.

23. The semiconductor apparatus according to claim 13, wherein the contact portion is disposed at a position outside an edge of the first semiconductor layer in the plan view.

24. A photoelectric conversion system comprising:
the semiconductor apparatus according to claim 1; and
a signal processing unit configured to generate an image by using a signal output from the semiconductor apparatus.

25. A moving body that includes the semiconductor apparatus according to claim 1, the moving body comprising a control unit configured to control movement of the moving body by using a signal output from the semiconductor apparatus.
